(19) United States
(12) Patent Application Publication
(10) Pub. No.: US 2015/0380902 A1
(43) Pub. Date: Dec. 31, 2015

(54) SURFACE EMITTING LASER AND OPTICAL COHERENCE TOMOGRAPHY USING THE SURFACE EMITTING LASER

(71) Applicant: CANON KABUSHIKI KAISHA, Tokyo (JP)

(72) Inventor: Yasuhiro Nagatomo, Kawasaki-shi (JP)

(21) Appl. No.: 14/754,873

(22) Filed: Jun. 30, 2015

(30) Foreign Application Priority Data
Jun. 30, 2014 (JP) 2014-135388

(51) Int. Cl. H01S 5/183; G01B 9/02

(52) U.S. Cl. CPC H01S 5/18361; G01B 9/02091

(57) ABSTRACT

A surface emitting laser including a lower reflecting mirror, an active layer, and an upper reflecting mirror in that order, and having a gap portion between the active layer and the upper reflecting mirror, includes a movable portion provided on an optical path of the gap portion and having a refractive index different from a refractive index of the gap portion. A wavelength of light to be emitted is changed by changing positions in an optical-axis direction of at least two of the movable portion, the upper reflecting mirror, and the lower reflecting mirror.

### BACKGROUND OF THE INVENTION

1. Field of the Invention

The present invention relates to a wavelength variable surface emitting laser, and an optical coherence tomography using the surface emitting laser.

2. Description of the Related Art

Since a wavelength variable laser that can change its laser oscillation wavelength is expected to be applied to various fields such as communication, sensing, and imaging, the wavelength variable laser is actively studied and developed in recent years.

There is known, as a type of wavelength variable laser, a wavelength variable VCSEL structure that controls the laser oscillation wavelength of a vertical cavity surface emitting laser by micro electro mechanical systems (MEMS) technology. Hereinafter, a vertical cavity surface emitting laser may be occasionally referred to as VCSEL, and a wavelength variable VCSEL using MEMS may be occasionally referred to as MEMS-VCSEL.

VCSEL is typically configured such that an active layer is sandwiched between a pair of reflecting mirrors such as distributed Bragg reflectors (DBRs), and oscillates a laser beam with a wavelength corresponding to a cavity length that is determined by an optical distance between the pair of reflecting mirrors. In MEMS-VCSEL, the laser oscillation wavelength can be changed by mechanically moving the position of one of the reflecting mirrors and hence changing the cavity length (the specification of U.S. Pat. No. 6,549,687).

### SUMMARY OF THE INVENTION

In VCSEL of related art described in the specification of U.S. Pat. No. 6,549,687, the inventor of the present invention found that a mode hop phenomenon occurs if the wavelength is continuously changed. A mode hop is a phenomenon in which an oscillated laser beam is changed from a certain longitudinal mode to another longitudinal mode. To be specific, in the phenomenon, the oscillation wavelength becomes rapidly short while the oscillation wavelength is changed to become long, or the oscillation wavelength becomes rapidly long while the oscillation wavelength is changed to become short. If such a mode hop occurs, when the oscillation wavelength is changed, the oscillation is hardly continued in a certain mode. Hence, the variable width of the oscillation wavelength becomes small.

Accordingly, the invention provides a surface emitting laser that can enlarge a wavelength variable width by restricting a mode hop of a longitudinal mode.

According to an aspect of the invention, there is provided a surface emitting laser including a lower reflecting mirror, an active layer, and an upper reflecting mirror in that order, and having a gap portion between the active layer and the upper reflecting mirror. The surface emitting laser includes a movable portion provided on an optical path of the gap portion and having a refractive index different from a refractive index of the gap portion. A wavelength of light to be emitted is changed by changing positions in an optical-axis direction of at least two of the movable portion, the upper reflecting mirror, and the lower reflecting mirror.

Further features of the present invention will become apparent from the following description of exemplary embodiments with reference to the attached drawings.

### BRIEF DESCRIPTION OF THE DRAWINGS

FIG. 1 is a schematic cross-sectional view showing a structure of a surface emitting laser according to an exemplary embodiment of the invention.

FIGS. 2A to 2C illustrate examples of calculation results indicative of light-intensity distributions of the surface emitting laser according to the exemplary embodiment of the invention.

FIGS. 3A and 3B illustrate calculation results indicative of optical characteristics of the surface emitting laser according to the exemplary embodiment of the invention.

FIG. 4 illustrates a calculation result indicative of the relationship between the light intensity ratio and the thickness of a movable portion of the surface emitting laser according to the exemplary embodiment of the invention.

FIG. 5 is a schematic cross-sectional view showing a structure of a surface emitting laser according to EXAMPLE 1 of the invention.

FIGS. 6A and 6B illustrate calculation results indicative of optical characteristics of the surface emitting laser according to EXAMPLE 1 of the invention.

FIG. 7 is a schematic illustration showing an optical coherence tomography according to the exemplary embodiment of the invention.

FIG. 8 is a schematic cross-sectional view showing a structure of MEMS-VCSEL of related art.

FIGS. 9A and 9B illustrate calculation results explaining a problem of MEMS-VCSEL of related art.

FIG. 10 is a schematic cross-sectional view explaining an example configuration of a surface emitting laser according to EXAMPLE 2 of the invention.

FIG. 11 is a schematic cross-sectional view explaining an example configuration of a surface emitting laser according to EXAMPLE 3 of the invention.

### DESCRIPTION OF THE EMBODIMENTS

A wavelength variable vertical cavity surface emitting laser (VCSEL) according to an exemplary embodiment of the invention is described below.

First, words to be used in this specification are defined.

In this specification, the side near a substrate of a laser element is defined as the lower side, and the side opposite to the substrate is defined as the upper side.

In this specification, a center wavelength is used as a wavelength at the center of a wavelength range of a laser beam that can be emitted from a surface emitting laser. That is, the center wavelength represents the wavelength at the center between the shortest wavelength and the longest wavelength that can be provided by laser oscillation. The wavelength that can be provided by laser oscillation is determined by the variation width of a cavity length, the reflection band of a reflecting mirror, the gain band of an active layer, etc. At the time of design, the center wavelength is basically set and configurations of respective elements are determined in accordance with the center wavelength. Also, in this specification, the “center” of a movable portion or an active layer represents the position at a half of the thickness in an optical-axis direction. The optical-axis direction is a direction connecting an upper reflecting mirror and a lower reflecting mirror (described later) and a direction perpendicular to a principal surface of a substrate.

Also, in this specification, 1λ represents 1 wavelength. The wavelength at this time is the center wavelength unless otherwise noted.

The calculation result in this specification was obtained by calculating a distribution of electromagnetic fields in a cavity by using a transfer matrix method with regard to boundary conditions of Maxwell's equations.

### Surface Emitting Laser

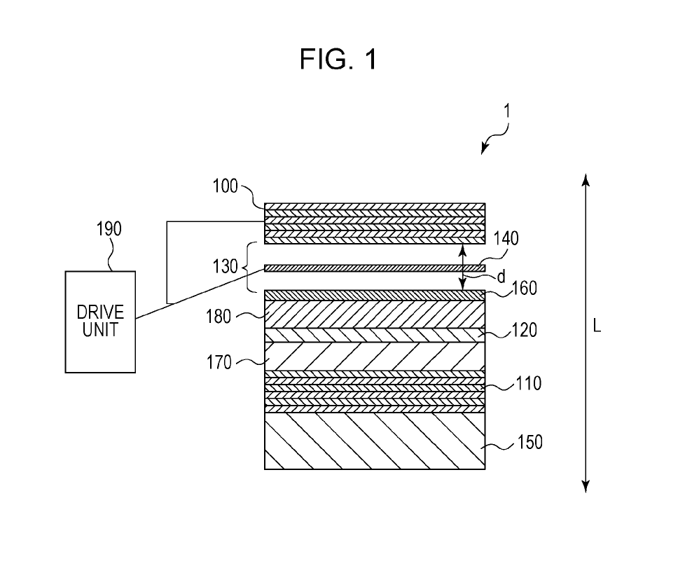

FIG. 1 is a schematic cross-sectional view showing a configuration of a surface emitting laser according to this exemplary embodiment.

A surface emitting laser 1 according to this exemplary embodiment includes a substrate 150, a lower reflecting mirror 110, a lower cladding layer 170, an active layer 120, an upper cladding layer 180, an antireflection film 160, and an upper reflecting mirror 100 arranged in that order. Also, a gap portion 130 is provided between the active layer 120 and the upper reflecting mirror 100.

A movable portion 140 having a refractive index different from the diffractive index of the gap portion 130 is provided on an optical path of the gap portion 130. In this exemplary embodiment, distributed Bragg reflectors (DBRs) each formed of a multilayer film are used as the upper reflecting mirror 100 and the lower reflecting mirror 110. A region sandwiched between the upper reflecting mirror 100 and the lower reflecting mirror 110 serves as a cavity, and forms a standing light wave. The upper reflecting mirror 100 can be displaced in the optical-axis direction (direction indicated by double sided arrow L in FIG. 1). The gap portion 130 has a length d (hereinafter, occasionally referred to as air-gap length) between the upper reflecting mirror 100 and the antireflection film 160. When the length d is changed, the cavity length is changed, and the resonant wavelength is changed. The length d of the gap portion is a distance on the optical axis between a semiconductor stack body including the active layer 120 and the lower reflecting mirror 110, and the upper reflecting mirror 100. For example, in FIG. 1, the length d is the distance between the upper reflecting mirror 100 and the upper cladding layer 180 if the antireflection film 160 is not formed, and the length d is the distance between the upper reflecting mirror 100 and the active layer 120 if the antireflection film or the upper cladding layer is not provided.

Hence, the surface emitting laser 1 according to this exemplary embodiment uses a drive unit 190 that changes the position of the upper reflecting mirror 100 to change the position of the upper reflecting mirror 100 in the optical-axis direction, and hence changes the air-gap length. Accordingly, the wavelength of light to be emitted can be changed.

In the surface emitting laser according to this exemplary embodiment, the position in the optical-axis direction (L in FIG. 1) of the movable portion 140 is changed, so that the threshold gain of a specific longitudinal mode is set to be relatively smaller than that of another longitudinal mode. Accordingly, a mode hop can be restricted and the wavelength variable width can be enlarged.

To be specific, the above-described effect can be attained by properly controlling the position of the movable portion 140, in accordance with a change in air-gap length and a change in resonant wavelength (laser oscillation wavelength).

The proper control mentioned here represents controlling the position in the optical-axis direction of the movable portion 140 so that the amplitude of the light intensity between the movable portion 140 and the lower reflecting mirror 110 is larger than the amplitude of the light intensity between the movable portion 140 and the upper reflecting mirror 100. That is, if the movable portion 140 is not provided, the light-intensity distribution from the upper reflecting mirror 100 to the lower reflecting mirror 110 does not have a bias. However, by providing the movable portion 140, a bias is generated in the light-intensity distribution so that the amplitude of the light intensity is increased in the active layer 120. In other words, the movable portion 140, the upper reflecting mirror 100, and the lower reflecting mirror 110 are positioned so that the amplitude of the standing light wave formed between the movable portion 140 and the lower reflecting mirror 110 is larger than the amplitude of the standing light wave formed between the movable portion 140 and the upper reflecting mirror 100. As the result, the threshold gain in a specific mode can be decreased. In contrast, the threshold gain of another neighbor mode is relatively increased, and hence the difference between the threshold gain in the specific mode and the threshold gain in the other neighbor mode is increased. Accordingly, a mode hop hardly occurs, and oscillation easily occurs in the specific mode.

### Description for Principle

The principle that the effect of the invention is generated is described in detail.

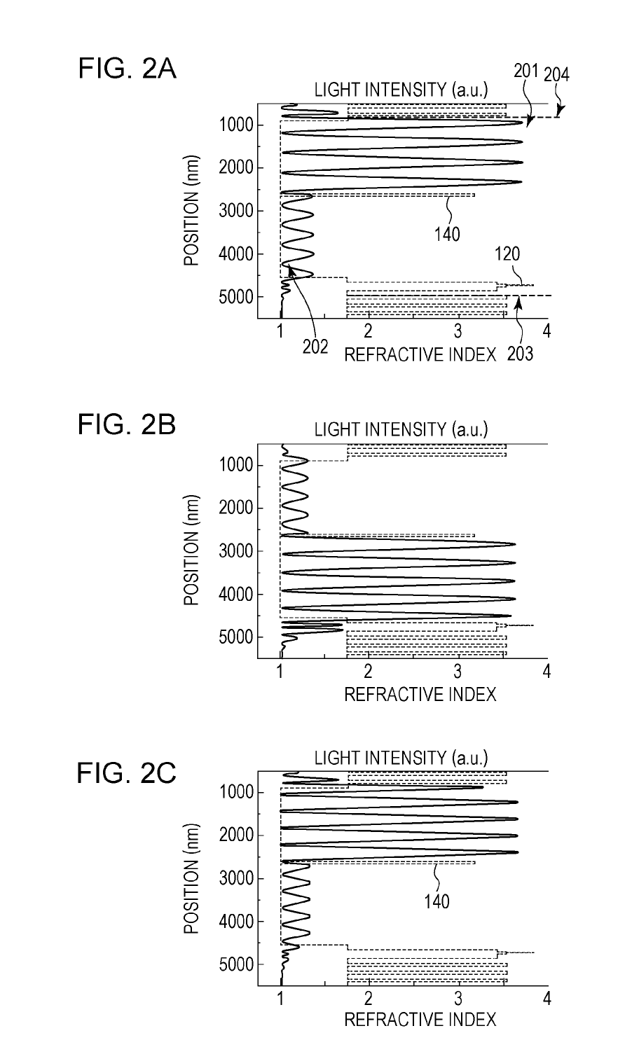

FIGS. 2A to 2C illustrate examples of calculation results for explaining occurrence of differences in light distribution among different longitudinal modes in the surface emitting laser according to this exemplary embodiment.

The configuration of the surface emitting laser serving as a calculation subject is a case in which the surface emitting laser shown in FIG. 1 has an air-gap length of 3600 nm.

FIGS. 2A to 2C each shows a graph of a light-intensity distribution around the gap portion 130. The refractive index distribution is indicated by a broken line, and the light-intensity distribution is indicated by a thick solid line. Referring to reference numerals added to the graph in FIG. 2A, the numeral 120 represents the center axis of the active layer, and the numeral 140 represents the position of the movable portion. FIGS. 2B and 2C have the numerals similarly.

FIGS. 2A to 2C show the results of three different longitudinal modes so that the cavity lengths are 5λ, 5.5λ, and 6λ when the cavity length is constant. In FIG. 2A, reference numeral 201 represents a loop of a standing light wave, reference numeral 202 represents a node of the standing light wave, reference numeral 203 represents an upper end of the lower reflecting mirror, and reference numeral 204 represents the lower end of the upper reflecting mirror. Corresponding positions in FIGS. 2B and FIG. 2C are similarly illustrated.

Referring to FIGS. 2A to 2C, it is found that a bias in light distribution is generated in the vertical direction with respect to the movable portion 140 as the boundary.

In FIGS. 2A and 2C, a bias is generated so that the amplitude of the light intensity is increased in a region between the movable portion 140 and the upper reflecting mirror 100. In contrast, in FIG. 2B, a bias is generated so that the amplitude of the light intensity is increased in a region between the movable portion 140 and the lower reflecting mirror 100.

If the light distribution is biased to the lower reflecting mirror side when viewed from the movable portion 140 as shown in FIG. 2B, the amplitude of the light intensity in the active layer is increased. As the overlap between the active layer and the light distribution is increased, optical amplification is more efficiently performed. Hence, laser oscillation can occur with a small gain.

In contrast, if the light distribution is biased to the upper reflecting mirror side when viewed from the movable portion 140 as shown in FIG. 2A or 2C, the amplitude of the light intensity in the active layer is increased. Then, a large gain is required for laser oscillation unlike the case in FIG. 2B. The amplitude may employ the average value of respective amplitudes of the light distribution between the movable portion and the lower reflecting mirror. As the result, the threshold gains in the one-order lower and one-order higher longitudinal modes shown in FIGS. 2A and 2C are relatively larger than the longitudinal mode shown in FIG. 2B, and a mode hop is restricted.

In this calculation examples, as shown in FIG. 2B, the center in the optical-axis direction of the movable portion 140 is located between a loop of the light distribution and a node at the lower reflecting mirror side among nodes neighbor of the loop. In contrast, in each of FIGS. 2A and 2C, the center in the optical-axis direction of the movable portion 140 is located between a loop of the light distribution and a node at the upper reflecting mirror side among nodes neighbor of the loop.

Also, in FIG. 2B, the optical distance between the movable portion 140 and the lower reflecting mirror 110 is an integral multiple of a ½ wavelength, and the optical distance between the movable portion 140 and the upper reflecting mirror 100 is a value obtained by adding a ¼ wavelength to an integral multiple of a ½ wavelength. Also, in each of FIGS. 2A and 2C, the optical distance between the movable portion 140 and the lower reflecting mirror 110 is a value obtained by adding a ¼ wavelength to an integral multiple of a ½ wavelength, and the optical distance between the movable portion 140 and the upper reflecting mirror 100 is an integral multiple of a ½ wavelength.

With regard to the results, at least in this calculation examples, if the movable portion 140 is arranged at the position shown in FIG. 2B, the light distribution is biased toward the lower reflecting mirror side when viewed from the movable portion 140. If the movable portion 140 is arranged at the position shown in FIG. 2A or 2C, the light distribution is biased toward the upper reflecting mirror side when viewed from the movable portion 140. The positions of the loop and node of the standing light wave are determined on the basis of the laser oscillation wavelength λ, the optical distance from the lower reflecting mirror 110, and the phase change at reflection by the lower reflecting mirror 110. Hence, the position of the movable portion can be determined in accordance with these factors.

If the phase change at light reflection by the lower reflecting mirror 110 is 0 and represents free-end reflection, the loop is located at a distance of λ/2×m and the node is located at a distance of λ/2×(m−1)+λ/4 from the upper end of the lower reflecting mirror (m is a natural number, which will be also applied to the following description).

If the phase change at light reflection by the lower reflecting mirror 110 is π and represents fixed-end reflection, the loop is located at a distance of λ/2×(m−1)+λ/4 and the node is located at a distance of λ/2×(m−1) from the upper end of the lower reflecting mirror.

That is, the light distribution is biased toward the lower reflecting mirror side if the distance L from the upper end of the lower reflecting mirror 110 to the center in the optical-axis direction of the movable portion meets the relationship in Expression (1) in case of free-end reflection or the relationship in Expression (2) in case of fixed-end reflection.

λ/2×(m−1)+λ/4<L<λ/2×m (1)

λ/2×(m−1)<L<λ/2×(m−1)+λ/4 (2)
If the phase change at light reflection by the lower reflecting mirror is not 0 or π, the movable portion is provided at an intermediate position between the above-described two cases, in accordance with the amount of phase change. Since the light distribution in the cavity is changed in accordance with the laser oscillation wavelength of the surface emitting laser, the position of the movable portion is required to be changed in accordance with the wavelength intended for oscillation. Also, since the laser oscillation wavelength is changed in accordance with the position of the upper reflecting mirror, the position of the movable portion is required to be changed in accordance with the position of the upper reflecting mirror. In this exemplary embodiment, for example, the movable portion 140 is arranged at a position near the center of the optical distance of the cavity, and the movable portion 140 is displaced in the same direction as the displacement direction of the upper reflecting mirror by a half of the displacement amount of the upper reflecting mirror 100. Accordingly, the above-described light distribution can be formed.

Also, if the upper reflecting mirror is periodically displaced and driven to repetitively perform wavelength sweeping, the movable portion and the upper reflecting mirror may be displaced desirably synchronously, and may be displaced desirably in the same period.

At this time, the frequency of the vibration may be the mechanical resonant frequency of the upper reflecting mirror and the movable portion, or may be other frequency. Also, if the initial position of the movable portion is near the center of the gap portion, the ratio of the displacement of the movable portion to the displacement of at least one of the upper reflecting mirror and the lower reflecting mirror may be desirably 1:2.

In this exemplary embodiment, if the displacement of the upper reflecting mirror is larger than the displacement of the movable portion, the above-described light distribution can be formed. Owing to this, if the vibration is made with a frequency closer to the resonant frequency of the upper reflecting mirror than the resonant frequency of the movable portion, the amplitude of the upper reflecting mirror is easily increased. This may be occasionally convenient.

### Detailed Description for Problem of Related Art

A problem that is found by the inventor of the present invention is described in detail below. The problem is owned by VCSEL of related art and is that the above-described movable portion 140 is not provided and a proper light-intensity distribution is not formed.

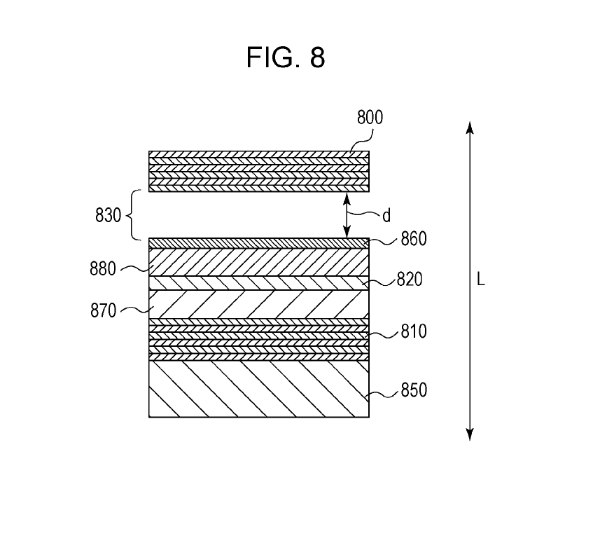

FIG. 8 is a schematic cross-sectional view showing general MEMS-VCSEL of related art.

MEMS-VCSEL in FIG. 8 is configured of a compound semiconductor based on GaAs, has a center wavelength of 850 nm, and is designed so that the wavelength is variable around the center wavelength. A resonant structure in which an active layer 820 and a gap portion 830 are sandwiched between an upper reflecting mirror 800 and a lower reflecting mirror 810 is arranged on a substrate 850. Also, the active layer 820 is sandwiched between a lower cladding layer 870 and an upper cladding layer 880.

Also, distributed Bragg reflectors (DBRs) each formed of a multilayer film are used as the upper reflecting mirror and the lower reflecting mirror. An antireflection film 860 is formed between the gap portion 830 and the upper cladding layer 880.

The optical distance between the upper reflecting mirror 800 and the lower reflecting mirror 810 is the cavity length. Also, by moving the upper reflecting mirror 800 in the optical-axis direction (L), the length d of the gap portion 830 can be changed and hence the cavity length can be changed. Accordingly, the laser oscillation wavelength can be changed.

In general, a plurality of optical modes are present in a cavity. A mode classified on the basis of a difference in light distribution in the optical-axis direction of the cavity is called longitudinal mode, and a mode classified on the basis of a difference in light distribution in a direction perpendicular to the optical axis is called transverse mode.

The order of the longitudinal mode is defined by the number of optical wavelengths involved in the optical distance (cavity length) in the optical-axis direction. A mode involving a smaller number is called low-order longitudinal mode, and a mode involving a larger number is called high-order longitudinal mode.

Here, a state in which laser oscillation occurs in a certain longitudinal mode is considered. When the upper reflecting mirror 800 is moved upward from the state, the cavity length is increased, and the laser oscillation wavelength is shifted to the long wavelength side. The laser oscillation wavelength is continuously changed in accordance with the displacement of the upper reflecting mirror. However, if the displacement of the upper reflecting mirror 800 exceeds a certain value, laser oscillation occurs in a one-order higher longitudinal mode, and the laser oscillation wavelength discontinuously may jump to the short wavelength side.

If the upper reflecting mirror 800 is moved downward similarly, the laser oscillation wavelength is shifted to the short wavelength side. However, if the displacement of the upper reflecting mirror 800 exceeds a certain value, laser oscillation occurs in one-order lower longitudinal mode. As the result, the laser oscillation wavelength may discontinuously jump to the long wavelength side.

As described above, a phenomenon, in which the wavelength is discontinuously changed because the mode of laser oscillation is changed, is generally called mode hop.

In MEMS-VCSEL, when the wavelength is continuously changed, if the wavelength is changed by a certain degree or more, a mode hop may occur and the wavelength may be rapidly changed. To be specific, the oscillation wavelength becomes rapidly short while the oscillation wavelength is changed to become long, or the oscillation wavelength becomes rapidly long while the oscillation wavelength is changed to become short. Hence, there is a problem in which the wavelength variable width is limited. Described in more detail below is the reason why the wavelength width is narrowed as the result that a mode hop occurs.

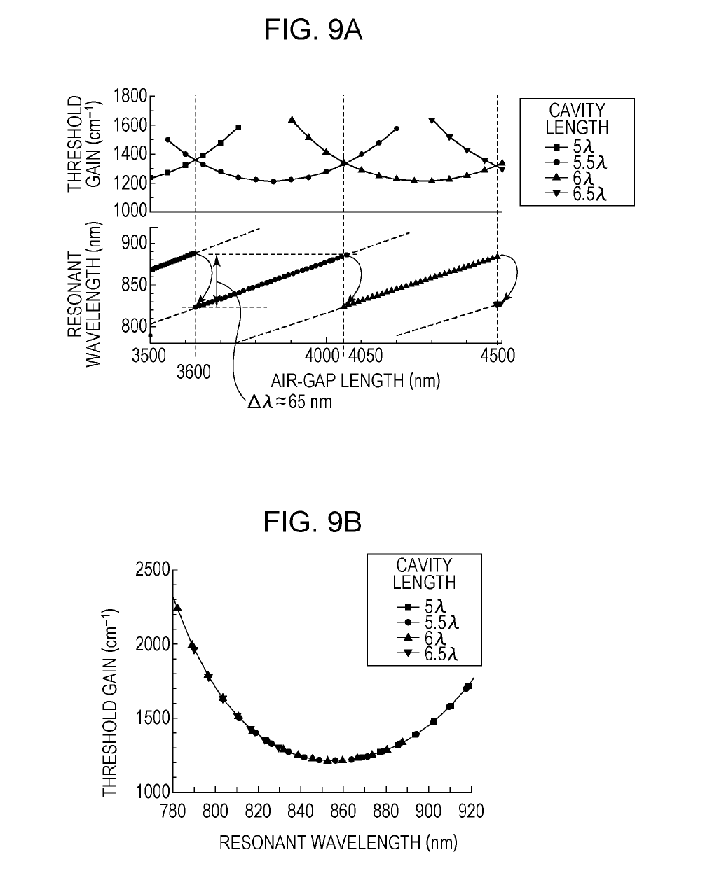

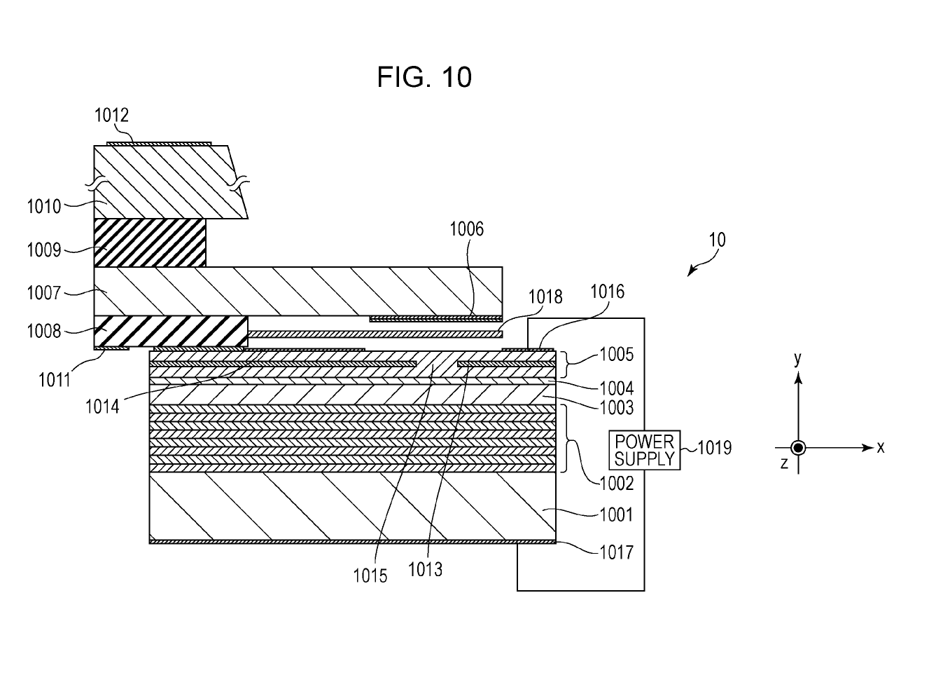

FIG. 9A shows an example of calculation for the relationship of the resonant wavelength and the gain (threshold gain) required for laser oscillation with respect to the length (hereinafter, occasionally referred to as air-gap length) of the gap portion 830 in the MEMS-VCSEL shown in FIG. 8. If a gain of the threshold gain or larger is provided by the active layer, laser oscillation occurs with the resonant wavelength.

In this calculation, the active layer is configured of a single-layer quantum well layer made of InGaAs with a thickness of 8 nm. Assuming that a gain is generated uniformly in the active layer, the gain per unit length required for laser oscillation was calculated.

In the range of the calculated wavelength and air-gap length, longitudinal modes corresponding to cavity lengths in a range from 5λ to 6.5λ are found. An upper graph in FIG. 9A plots the relationship between the air-gap length and the threshold gain. If the air-gap length is changed, the threshold gain is changed. Hence, it is found that there is a minimum value of the threshold gain for an air-gap length being different for each longitudinal mode.

Focusing on the minimum value of the threshold gain of a certain longitudinal mode, the threshold gain of the longitudinal mode is smaller than the threshold gain of another longitudinal mode while a change in air-gap length from the minimum value is smaller than a certain range. However, if the air-gap length is changed beyond the certain range, the threshold gain of the neighbor order longitudinal mode becomes smaller, and the magnitude relationship of the threshold gains is reversed.

A lower graph in FIG. 9A plots the relationship between the air-gap length and the resonant wavelength. The calculation result for the resonant wavelength in each longitudinal mode is indicated by a broken line. It is found that if the air-gap length is changed, the resonant wavelength in each mode is changed almost proportionally to the change in air-gap length.

A certain wavelength interval is provided between neighbor modes. The interval between the longitudinal modes may be occasionally called free spectral range (FSR).

In general, as the cavity length is increased, the longitudinal mode interval is decreased and the change in resonant wavelength in accordance with the change in air-gap length is also decreased (that is, the gradient of the lower graph in FIG. 9A is decreased). Owing to this, with regard to operation as a wavelength variable laser, the cavity length is desirably 10 wavelengths or smaller.

A resonant wavelength oscillated as a longitudinal mode with the smallest threshold gain read from the upper graph in FIG. 9A is indicated by a line with symbol marks in the lower graph in FIG. 9A.

Referring to FIG. 9A, as the air-gap length is increased, the resonant wavelength is shifted to the long wavelength side. If the amount of change in wavelength becomes a certain amount or larger, the threshold gain of a one-order higher longitudinal mode becomes smaller, and hence a mode hop may occur as indicated by an arrow in the drawing.

If a mode hop occurs, the wavelength is changed in an opposite direction. That is, if the wavelength is changed to be increased, the wavelength is decreased and the wavelength is increased again from the wavelength. Hence, the wavelength variable width is limited. For example, the air-gap length with which the wavelength can be continuously changed without occurrence of a mode hop in a longitudinal mode corresponding to a cavity length of 5.5λ is limited in a range from 3600 to 4050 nm. The wavelength variable width in this case is about 65 nm.

FIG. 9B plots again the calculation result in FIG. 9A while the horizontal axis represents the resonant wavelength and the vertical axis represents the threshold gain. Referring to FIG. 9B, the threshold gain is the most decreased around the center wavelength of 850 nm. There may be two reasons. The first reason is that since the DBRs of the upper and lower reflecting mirrors are designed on the basis of the center wavelength 850 nm, the reflectivity is increased as the wavelength approaches to the wavelength of 850 nm. In general, as the reflectivity of a reflecting mirror is higher, laser oscillation can occur with a smaller gain.

The second reason is that since the position of the active layer is designed to be aligned with the loop of the light distribution with the center wavelength of 850 nm, a positional deviation between the active layer and the loop of the light distribution is increased as the wavelength is more separated from the wavelength of 850 nm. If the light distribution in the active layer becomes small, the efficiency of optical amplification is decreased, and as the result, the threshold gain is increased.

Referring to FIG. 9B now, it is found that almost all the lines plotted for respective longitudinal modes are substantially overlapped. That is, there is substantially no difference in threshold gain among the longitudinal modes. It is found that the threshold gain is determined mainly on the basis of the wavelength. When laser oscillation occurs with a wavelength around the center wavelength in a certain longitudinal mode, if the air-gap length is changed, the resonant wavelength (laser oscillation wavelength) is separated from the center wavelength, and the threshold gain is increased accordingly. In contrast, the resonant wavelength of one-order higher or one-order lower longitudinal mode approaches to the center wavelength, and the threshold gain is decreased accordingly. When the change in air-gap length exceeds a certain value, the magnitude relationship of the threshold gains is reversed, and as the result, a mode hop occurs.

That is, the situation that a longitudinal mode with a wavelength near the center wavelength is switched as the result of a change in air-gap length is a factor of a mode hop.

It is to be noted that the above description does not consider a multimode state in which a plurality of longitudinal modes cause laser oscillation to occur simultaneously. In many cases, multimode oscillation is not desirable and a measure is taken to perform single mode operation. For example, single-mode oscillation can be performed by adjusting the current value or the like using the differences in threshold gain among the respective modes so that only a mode that most likely causes oscillation performs oscillation and the other modes do not cause oscillation.

In this specification, a phenomenon in which a mode that has relatively the lowest threshold gain and hence likely causes laser oscillation is switched to another longitudinal mode in a single-mode operation state in which only one longitudinal mode causes oscillation is called a mode hop.

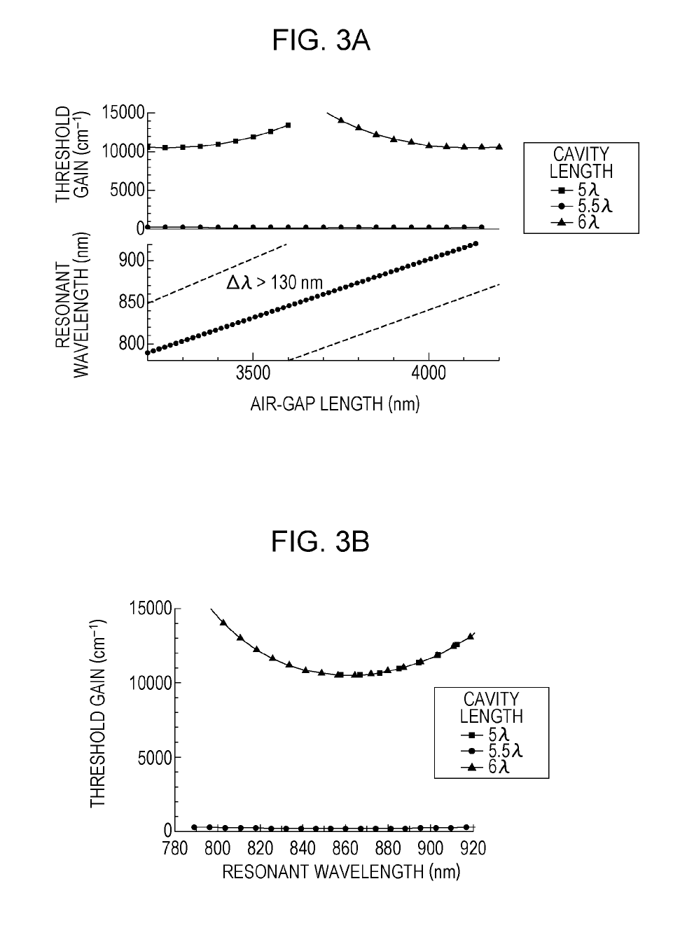

As described above, the wavelength variable width in a single mode of MEMS-VCSEL of related art is limited by a mode hop of a longitudinal mode. FIGS. 3A and 3B show the result of calculation for the relationship of the resonant wavelength and the gain (threshold gain) required for laser oscillation with respect to the change in air-gap length in the structure shown in FIG. 1.

Referring to an upper graph in FIG. 3A, it is found that the threshold gain is relatively small only in a specific longitudinal mode unlike FIG. 9A.

In the calculated range of wavelength and air-gap length, it is recognized that the threshold gain of a longitudinal mode corresponding to a cavity length of 5.5λ is constantly small, the magnitude relationship between the threshold gains is not reversed in a wide wavelength range of wavelengths equal to or larger than 130 nm, and hence a mode hop is restricted.

As compared with the calculation result of VCSEL of related art shown in FIG. 9A, it is found that the surface emitting laser according to this exemplary embodiment can provide the wavelength variable width that is twice or more of the wavelength variable width of the structure of related art.

FIG. 3B shows a graph expressing the calculation result in FIG. 3A in a different form. FIG. 3B plots again the calculation result in FIG. 3A while the horizontal axis represents the resonant wavelength and the vertical axis represents the threshold gain, similarly to the calculation result shown in FIG. 9B.

The plotted lines for the longitudinal modes with the cavity lengths being 5λ and 6λ are substantially overlapped; however, only the threshold gain of the longitudinal mode being 5.5λ is relatively small.

As described above, in the surface emitting laser according to this exemplary embodiment, it is found that the threshold gain of only a specific longitudinal mode is small in a wide wavelength range, and wavelength sweeping in a wide band can be performed without occurrence of a mode hop. It is to be noted that the surface emitting laser according to this exemplary embodiment attains not only the effect of restricting a mode hop, but also an effect that the threshold gain becomes smaller than that of the related art structure in a specific longitudinal mode and hence laser oscillation can be easily performed as found through comparison between FIGS. 3B and 9B.

### Movable Portion

In this exemplary embodiment, the movable portion is not particularly limited as long as the movable portion has a refractive index different from the refractive index of the gap portion to change the light-intensity distribution in the cavity. Also, the refractive index of the movable portion is desirably higher than the refractive index of the gap portion. The movable portion can be displaced by, for example, a MEMS mechanism (described later).

The material of the movable portion is desirably properly selected with regard to the wavelength of light to be emitted by the surface emitting laser and the process of fabricating the movable portion. The specific material of the movable portion may be AlₓGa₍₁₋ₓ₎As (0<x<1, or more preferably, 0.6≦x≦0.8), GaAs, Si, or GaN. If a sacrificial layer process is used to fabricate the movable portion by using such a material, the combination of the materials of the movable portion, sacrificial layer, and etchant may be as follows. That is, the materials of “the movable portion, sacrificial layer, and etchant” may be respectively desirably “AlₓGa₍₁₋ₓ₎As (0<x<1), GaAs, a citric acid solution and aqueous hydrogen peroxide,” “GaAs, AlGaInP or AlInP or GaInP, hydrochloric acid,” “GaAs, AlₓGa₍₁₋ₓ₎As (0.9≦x), BHF,” “Si, SiO₂, BHF,” or “GaN, (AlInN)Ohd x, NTA:KOH.”

### Thickness of Movable Portion

An optimal thickness of the movable portion according to this exemplary embodiment is described. For description, a value called light intensity ratio is defined as a numerical value representing the magnitude of a bias of a light distribution.

The light-intensity distribution is calculated as shown in FIGS. 2A to 2C, and the magnitude of the peak located at the lower reflecting mirror side of the movable portion in the gap is normalized by using the magnitude of the peak located at the upper reflecting mirror side of the movable portion. The normalized value is defined as the light intensity ratio. Accordingly, as the light intensity ratio is larger, it can be said that the light distribution is biased toward the lower reflecting mirror side.

In other words, it is desirable that light in a mode for laser oscillation is more biased toward the active layer side, or in this exemplary embodiment, toward the lower reflecting mirror side. That is, a structure with a large light intensity ratio is desirable.

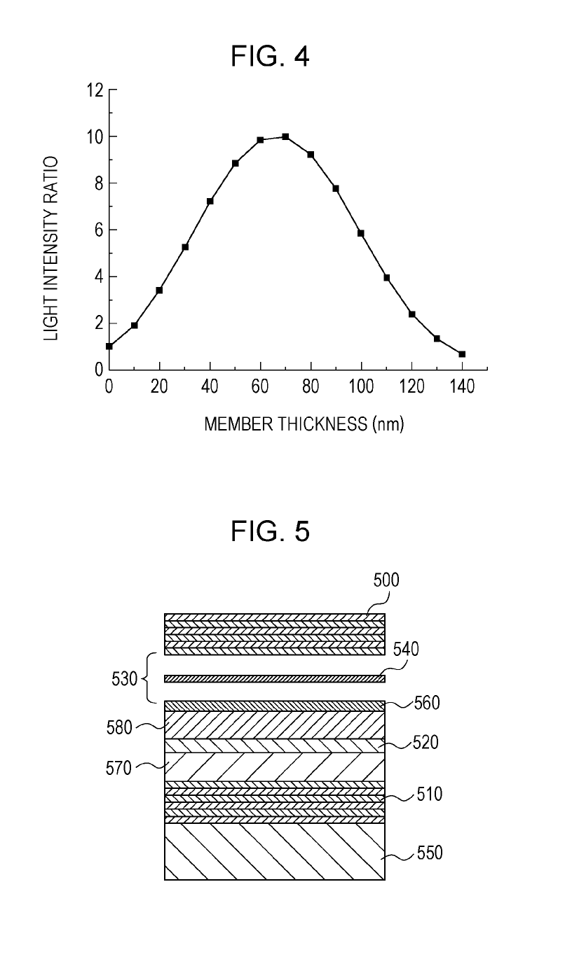

FIG. 4 shows the calculation result for the relationship between the thickness of the movable portion 140 and the above-described light intensity ratio in the VCSEL shown in FIG. 1. It is to be noted that if the thickness of the movable portion is changed, the air-gap length is adjusted so as to obtain a substantially equivalent laser oscillation wavelength.

In the structure of related art with the thickness of the movable portion being 0 nm, the light intensity ratio is 1, and a bias is not found in the light-intensity distribution of the gap portion.

In contrast, when the thickness of the movable portion is a thickness slightly smaller than 70 nm, the light-intensity ratio becomes the maximum value. With this thickness, the optical thickness obtained by multiplying the thickness of the movable portion by the refractive index of the movable portion corresponds to ¼ of the center wavelength.

When the thickness of the movable portion exceeds about 130 nm, the light intensity ratio becomes smaller than 1. The situation in which the light intensity ratio is smaller than 1 represents that the light distribution is biased to the upper side. With this thickness, the optical thickness corresponds to ½ of the center wavelength. Accordingly, in this exemplary embodiment, the optical thickness of the movable portion is preferably 130 nm or smaller, and is more preferably in a range from 35 nm to 105 nm.

Therefore, the optical thickness of the movable portion is preferably larger than 0 and smaller than ½ of the center wavelength.

More preferably, the optical thickness of the movable portion is larger than ⅛ and smaller than ⅜ of the center wavelength, as the range for obtaining the light intensity ratio being a half or more of the optimal value.

Alternatively, an optically equivalent effect can be obtained even if the optical thickness is obtained by adding a thickness of an integral multiple of ½ of the center wavelength to the above-described value.

### Upper Reflecting Mirror and Lower Reflecting Mirror

In the surface emitting laser according to this exemplary embodiment, the upper and lower reflecting mirrors are not particularly limited as long as the mirrors have reflectivities sufficient for laser oscillation. For example, DBR made of a dielectric or semiconductor multilayer film, a metal film, or a diffraction grating may be used.

An example of a dielectric multilayer film may be a film having a plurality of pairs of a silicon oxide layer (SiO₂ layer) serving as a low-refractive-index layer and a titanium oxide layer (TiO₂ layer) serving as a high-refractive-index layer.

In contrast, if a semiconductor multilayer film is used, the material configuring the semiconductor layer desirably has a material expressed by AlₓGa₍₁₋ₓ₎As (0≦x≦1). For example, a semiconductor multilayer film having a plurality of pairs of a GaAs layer serving as a high-refractive-index layer and an AlₓGa₍₁₋ₓ₎As layer (0.9≦x≦1) serving as a low-refractive-index layer. Also, AlAs satisfying x=1 may be used as the low-refractive-index layer.

The reflection bandwidth for high reflectivity and reflectivity can be controlled by properly changing the number of pairs of multilayer-film mirrors (DBRs).

The structures and materials of the upper reflecting mirror and lower reflecting mirror according to this exemplary embodiment can be independently selected.

Also, one of the upper reflecting mirror and the lower reflecting mirror may be a diffraction grating, for example, a high contrast grating (hereinafter occasionally abbreviated as HCG) mirror. The HCG mirror has a configuration in which a material with a high refractive index and a material with a low refractive index are alternately periodically arranged in the in-plane direction. An example of the HCG mirror may be a periodic structure including a high-refractive-index region (AlGaAs portion) and a low-refractive-index region (gap portion) provided with a periodic gap by processing a semiconductor layer such as an AlGaAs layer.

In the case of wavelength variable VCSEL, it is desirable to use a light-weight reflecting mirror for the reflecting mirror to be moved (in FIG. 1, the upper reflecting mirror) because the wavelength variable speed is increased. Owing to this, in this exemplary embodiment, the upper reflecting mirror desirably uses a HCG mirror with a thin (light-weight) configuration, instead of a multilayer-film mirror (DBR) with a thick (heavy) configuration.

In the surface emitting laser according to this exemplary embodiment, the upper reflecting mirror is used as the reflecting mirror at the light extraction side; however, the lower reflecting mirror may be used as the reflecting mirror at the light extraction side. The reflecting mirror at the light extraction side has a peak reflectivity that is lower than the reflectivity of the other reflecting mirror.

The reflecting mirror for extracting light preferably has a value of reflectivity in a range from 99.0% to 99.5%.

Also, in general, comparing DBR configured of a dielectric with DBR configured of a semiconductor, the difference in refractive index of the dielectric DBR is more easily increased, and hence high reflectivity can be realized with a smaller number of stacked layers. In contrast, DBR configured of a semiconductor has advantages for processes that the lower reflecting mirror, active layer, and upper reflecting mirror can be collectively formed by crystal growth, and conductivity can be provided by doping. In the case of forming DBR with a semiconductor that cannot have a large difference in refractive index as compared with a dielectric, high reflectivity and a wide reflection band can be obtained by increasing the number of stacked layers.

In the above-described example, the surface emitting laser according to this exemplary embodiment drives the upper reflecting mirror and the movable portion. However, an exemplary embodiment may be employed in which at least two of the movable portion, the upper reflecting mirror, and the lower reflecting mirror are driven. At this time, at least two of the movable portion, the upper reflecting mirror, and the lower reflecting mirror may be displaced synchronously, and may be further displaced in the same period.

### Active Layer

The material of the active layer according to this exemplary embodiment is not particularly limited as log as the material generates light by injecting electric current, and may use a material used for a typical surface emitting laser. The composition and layer thickness of the material configuring the active layer may be properly selected in accordance with the wavelength intended for laser oscillation.

If light with a wavelength band around 850 nm is to be emitted, the active layer may use a material having a quantum well structure made of AlₙGa₍₁₋ₙ₎As (0≦n≦1). Also, if light with a wavelength band around 1060 nm is to be emitted, the active layer may use a material made of InₙGa₍₁₋ₙ)As (0≦n≦1).

Also, the active layer according to this exemplary embodiment desirably has a sufficiently wide gain. To be specific, the active layer desirably has a gain in a wider wavelength region than the reflection band of the upper reflecting mirror and the lower reflecting mirror. Such an active layer may be an active layer having a quantum well structure capable of emitting light at two or more different energy levels. Also, the quantum well structure may be configured of a plurality of layers to have a single quantum well or multiple quantum wells.

The material and structure of the active layer according to this exemplary embodiment may be properly selected in accordance with the wavelength intended for oscillation.

Also, the active layer according to this exemplary embodiment may emit light by irradiation with light and excitation, or by current injection. Hence, the surface emitting laser according to this exemplary embodiment or an optical coherence tomography (described later) may have an exciting light source for exciting the active layer or a power supply for injecting electric current to the active layer. An electrode is required if light is emitted by current injection; however, the electrode is omitted in this specification and drawings for convenience of description.

### First Cladding Layer and Second Cladding Layer

In this exemplary embodiment of the present invention, a cladding layer is provided for trapping light and a carrier. Also, in this exemplary embodiment of the present invention, the cladding layer also has a role as a spacer for adjusting the cavity length.

The first cladding layer and the second cladding layer according to this exemplary embodiment may each use an AlGaAs layer in which the composition of Al is properly selected in accordance with the wavelength band for emission. For example, if light with a wavelength band around 850 nm is to be emitted, an AlGaAs layer with an Al composition being 30% or higher may be used to avoid optical absorption. Also, if light with a wavelength band around 1060 nm is to be emitted, a GaAs layer or an AlGaAs layer with a certain composition may be used because optical absorption does not have to be considered. When the active layer emits light by current injection, the conductivity type of the first cladding layer is different from that of the second cladding layer. The thickness of the first cladding layer does not have to be the same as that of the second cladding layer when the cladding layer thicknesses are adjusted, and the layer thicknesses may be properly selected with regard to the thicknesses required for current dispersion.

### Current Confinement Layer

In this exemplary embodiment, a current confinement layer (not shown) for limiting a region where current injected to the laser flows may be provided if required. The current confinement layer is formed by hydrogen ion implantation or by selectively oxidizing an AlGaAs layer with an Al composition of 90% or higher arranged in the cladding layer. In this exemplary embodiment, the current confinement layer is not particularly required for a structure that emits light by irradiation of the active layer with light and excitation. The current confinement layer is suitably used for a structure that emits light by current injection.

### Gap Portion

A solid object is not generally present in the gap portion according to this exemplary embodiment. Hence, the gap portion may be in a vacuum, or fluid such as the air, inert gas, or liquid like water may be present in the gap portion with regard to the atmosphere. The vacuum state in this case represents a negative-pressure state with an atmospheric pressure being lower than the standard atmospheric pressure. In this specification, it is expected that the gap portion is filled with the air, and the calculation is performed with a refractive index of 1. The length of the gap portion (d in FIG. 1) may be determined with regard to the wavelength variable bandwidth and pull-in of the movable mirror. For example, in the cavity in which the gap portion is filled with the air, the wavelength variable width is 100 nm with a wavelength around the center wavelength of 1060 nm, and the cavity length is in a range from 3λ to 4λ, the length d of the gap portion is about 1 μm.

### Drive Unit

With the configuration to which the invention is applied, a unit configured to displace the upper reflecting mirror and the movable portion in the vertical direction may use a technology typically used in the field of MEMS. For example, static electricity, piezoelectricity, heat, electromagnetism, a fluid pressure, or the like, may be used.

For example, there may be a drive unit that provides driving by applying a voltage with use of a MEMS mechanism, or a drive unit that provides driving by using a piezoelectric material. That is, an electrostatic force is generated in the optical-axis direction between the upper reflecting mirror or the layer provided with the upper reflecting mirror and the stack body in which the lower reflecting mirror and the active layer are stacked, and the magnitude of the electrostatic force is changed, so that the upper reflecting mirror can be displaced. The electrostatic force may be similarly used even when the drive unit or the lower reflecting mirror is displaced.

The drive unit may have a cantilever beam structure or a double-support beam structure.

The drive unit according to this exemplary embodiment may be configured to displace the upper reflecting mirror, configured to displace the lower reflecting mirror, or configured to displace both. In this exemplary embodiment, to properly control the positional relationship between the upper reflecting mirror and the movable portion, a control unit configured to control the positions of the upper reflecting mirror and the movable portion may be provided.

Also, a plurality of the surface emitting lasers according to this exemplary embodiment may be arranged on the same plane, and may be used as a light source array.

### Optical Coherence Tomography

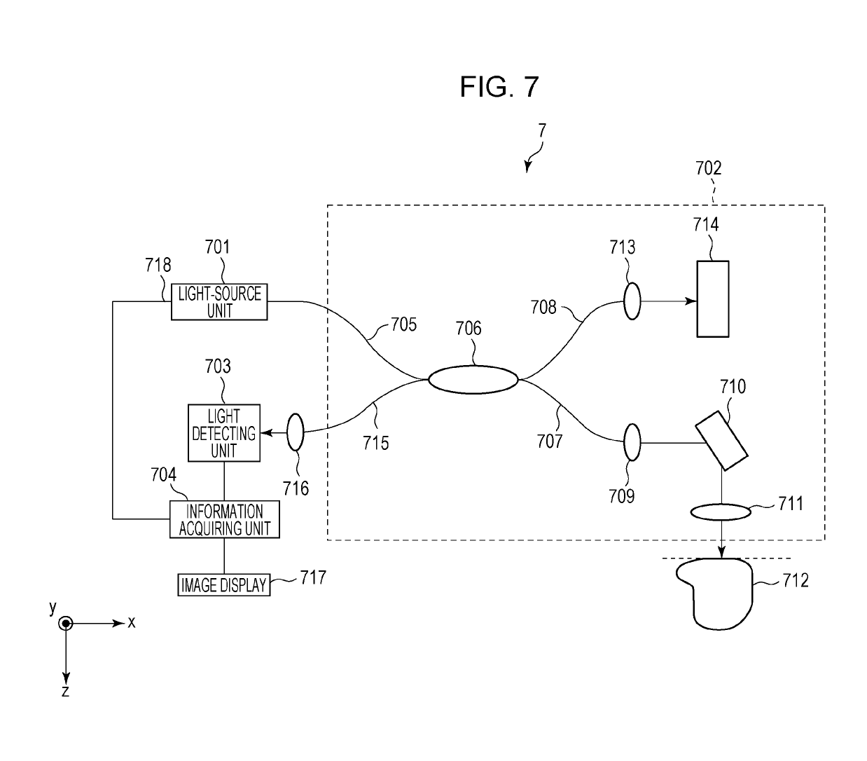

Since an optical coherence tomography (hereinafter, occasionally abbreviated as OCT) using the wavelength variable light source does not use a spectrometer, it is expected to acquire a tomographic image with a small loss in light quantity and a high S/N ratio. An example in which the surface emitting laser according to the exemplary embodiment is used for a light-source unit of OCT is described below with reference to FIG. 7.

An OCT device 7 according to this exemplary embodiment has a configuration including at least a light-source unit 701, an interference optical system 702, a light detecting unit 703, and an information acquiring unit 704; and can use the above-described surface emitting laser as the light-source unit 701. Although not shown, the information acquiring unit 704 has a Fourier transformer. The configuration that the information acquiring unit 704 has the Fourier transformer is not particularly limited as long as the information acquiring unit has a function of performing Fourier transform on input data. For example, the information acquiring unit 704 has an arithmetic unit and the arithmetic unit has a function of performing Fourier transform. To be specific, the arithmetic unit is a computer including CPU, and the computer executes an application having a Fourier transform function. For another example, the information acquiring unit 704 has a Fourier transform circuit having a Fourier transform function. Light output from the light-source unit 701 passes through the interference optical system 702, and is output as interfering light having information about an object 712 of a measurement object. The interfering light is received by the light detecting unit 703. The light detecting unit 703 may be a difference detecting type or a simple intensity monitoring type. Information of a temporal waveform with the intensity of the received interfering light is sent from the light detecting unit 703 to the information acquiring unit 704. The information acquiring unit 704 acquires the temporal waveform with the intensity of the received interfering light, performs Fourier transform, and hence acquires information (for example, information of a tomographic image) of the object 712. The light-source unit 701, the interference optical system 702, the light detecting unit 703, and the information acquiring unit 704 described above may be provided if desired.

A process from when light is oscillated from the light-source unit 701 to when the information of the tomographic image of the object as the measurement object is obtained is described in detail below.

The light output from the light-source unit 701 that changes the wavelength of light passes through a fiber 705, enters a coupler 706, and is split into irradiation light passing through an irradiation-light fiber 707 and reference light passing through a reference-light fiber 708. The coupler 706 is configured to operate in a single mode in the wavelength band of the light source. Various fiber couplers may be configured of 3 dB couplers. The irradiation light passes through a collimator 709, hence becomes parallel light, and is reflected by a mirror 710. The light reflected by the mirror 710 passes through a lens 711, is emitted on the object 712, and is reflected by respective layers in the depth direction of the object 712. In contrast, the reference light passes through a collimator 713, and is reflected by a mirror 714. In the coupler 706, interfering light is generated by the reflected light from the object 712 and the reflected light from the mirror 714. The interfering light passes through a fiber 715, passes through a collimator 716 to be collected, and is received by the light detecting unit 703. Information of the intensity of the interfering light received by the light detecting unit 703 is converted into electric information such as a voltage and is sent to the information acquiring unit 704. The information acquiring unit 704 processes the data of the intensity of the interfering light, or more particularly performs Fourier transform, and accordingly information of a tomographic image is obtained. The data of the intensity of the interfering light for Fourier transform is data generally sampled every equivalent number of waves by using k clock. However, data sampled at every equivalent wavelength may be also used.

The obtained information of the tomographic image may be sent from the information acquiring unit 704 to an image display 717 and displayed as an image. By scanning the mirror 710 in a plane perpendicular to the incidence direction of the irradiation light, a three-dimensional tomographic image of the object 712 of the measurement object can be obtained. Also, the light-source unit 701 may be controlled by the information acquiring unit 704 by using an electric circuit 718. Although not shown, the intensity of light output from the light-source unit 701 may be successively monitored and the data may be used for correcting the amplitude of a signal indicating the intensity of the interfering light. The surface emitting laser according to the exemplary embodiment of the invention can oscillate a laser beam in a wide band while restricting an increase in threshold current for emitting a laser beam and a decrease in light emission efficiency. The restriction is not limited to complete restriction to 0.

Hence, if the surface emitting laser according to this exemplary embodiment is used for the OCT device, a tomographic image with a high depth resolution can be obtained while electric current for outputting a laser beam is decreased.

The OCT device according to the exemplary embodiment is suitable for acquiring a tomographic image of a living body, such as an animal or a human, in the fields of ophthalmology, dentistry, dermatology, etc. The information relating to a tomographic image of a living body includes not only a tomographic image of a living body but also numerical data required for acquiring a tomographic image.

In particular, when a measurement object is an eye fundus of a human body, it is desirable to use numerical data to acquire information relating to a tomographic image of the eye fundus.

### Other Purposes

The surface emitting laser according to the exemplary embodiment of the invention can be used as a light source for optical communication or a light source for optical measurement, in addition to the above-described OCT.

### EXAMPLES

Examples of the invention are described below. It is to be noted that the invention is not limited to the configurations of the examples described below. For example, the kind, composition, shape, and size of a material may be properly changed within the scope of the invention.

In the following examples, the laser oscillation wavelength around 1060 nm and the laser oscillation wavelength around 850 nm are provided. However, an operation can be made with a desirable wavelength by selecting a proper material and a proper structure.

### Example 1

As EXAMPLE 1, VCSEL according to this example is described with reference to FIG. 5. FIG. 5 is a schematic cross-sectional view showing a layer structure of VCSEL according to this example.

The VCSEL according to this example is configured of a compound semiconductor based on GaAs, and is designed to perform wavelength sweeping around the center wavelength of 1060 nm.

An upper reflecting mirror 500, a gap portion 530, an antireflection film 560, an upper cladding layer 580, an active layer 520, a lower cladding layer 570, a lower reflecting mirror 510, and a GaAs substrate 550 are arranged in that order from the upper side. A movable portion 540 is arranged in the gap portion 530. The antireflection film 560 is formed of an AlAs oxide layer with an optical thickness of a ¼ wavelength.

The cavity length is configured to correspond to about 7.5λ when the center wavelength of 1060 nm is 1λ.

The upper reflecting mirror is DBR configured by alternately staking 36.5 pairs of Al_{0.4}Ga_{0.6}As and Al_{0.9}Ga_{0.1}As.

The lower reflecting mirror is DBR configured by alternately stacking 30 pairs of GaAs and AlAs and then alternately stacking 5 pairs of Al_{0.4}Ga_{0.6}As and Al_{0.9}Ga_{0.1}As.

The active layer is configured of a quantum well structure formed by alternately stacking a 8-nm-thick In_{0.27}Ga_{0.73}As layer and a 10-nm-thick GaAsP layer by 3 pairs.

The active layer is configured to emit light by current injection. In FIG. 5, an electrode for current injection is omitted.

The positions of the upper reflecting mirror 500 and the movable portion 540 can be changed in the vertical direction by an electrostatic force by application of a voltage. Also in this case, an electrode for voltage application is omitted in the drawing.

The movable portion 540 is arranged at a position separated by about 3λ from the upper reflecting mirror 500. The position of the movable portion 540 is controlled so that the movable portion 540 is displaced only by 60% of the displacement of the upper reflecting mirror 500.

The gap portion of this example is formed by using epitaxial growth and selective wet etching. The process is briefly described.

When epitaxial growth is performed, a portion corresponding to the gap portion is formed as a sacrificial layer of GaAs. Then, by using a mixed solution of water, citric acid, and aqueous hydrogen peroxide, as etchant, selective etching corresponding to the Al composition of AlGaAs can be performed. In this example, a solution in which a citric acid solution obtained by mixing water and citric acid (weight ratio of 1:1) and aqueous hydrogen peroxide with a density of 30% are mixed at the ratio of 4:1, and the solution is used as etchant. With this etchant, selective etching of GaAs and Al_{0.7}Ga_{0.3}As can be performed. By eliminating only the GaAs sacrificial layer, the gap portion can be formed. Also, even when the movable portion is formed in the gap portion, the selective etching can be used. With this configuration of this exemplary embodiment, a layer configuration in which the upper and lower sides of an Al_{0.7}Ga_{0.3}As layer are sandwiched by GaAs sacrificial layers by epitaxial growth and the above-described selective etching is performed. Accordingly, a configuration in which the upper and lower sides of the slab-shaped (thin-plate) Al_{0.7}Ga_{0.3}As layer are sandwiched by gap portions can be formed.

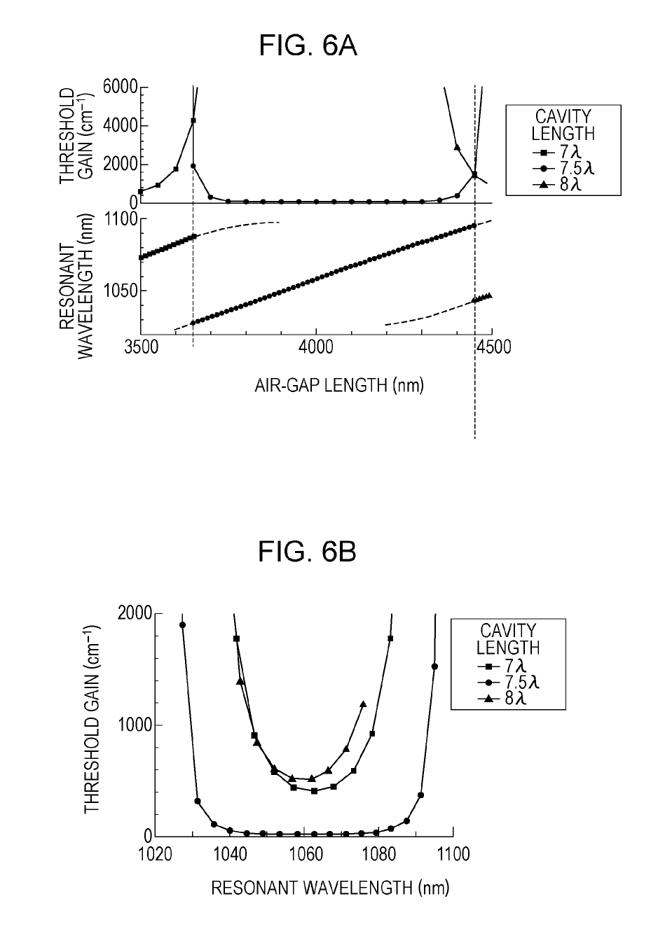

FIG. 6A shows the result of calculation for the relationship of the resonant wavelength and the gain (threshold gain) required for laser oscillation with respect to the air-gap length of the structure of VCSEL shown in FIG. 5.

Referring to an upper graph in FIG. 6A, it is found that the threshold gain is relatively small only in a specific longitudinal mode.

In a major part of the range of the calculated wavelength and the air-gap length, it can be recognized that the threshold gain of a longitudinal mode corresponding to a cavity length of 7.5λ is relatively small and a mode hop is restricted.

There is a region in which the threshold gain is reversed to the threshold gain in a neighbor order longitudinal mode. In this region, the resonant wavelength becomes outside the high-reflection band of the upper DBR and the threshold gain is rapidly increased. Accordingly, this wavelength actually has difficulty in causing laser oscillation regardless of the longitudinal mode. Hence, a mode hop does not actually occur.

FIG. 6B plots again the calculation result in FIG. 6A while the horizontal axis represents the resonant wavelength and the vertical axis represents the threshold gain.

The plotted lines for longitudinal modes with cavity lengths of 7λ and 8λ indicate close values; however, only the threshold gain of a longitudinal mode of 7.5λ is relatively small.

As described above, in the surface emitting laser according to this example, the threshold gain of only a specific longitudinal mode is small in a wide wavelength range, and wavelength sweeping in a wide band can be performed without occurrence of a mode hop.

### Example 2

FIG. 10 shows a schematic illustration explaining a configuration of a surface emitting laser according to EXAMPLE 2. In FIG. 10, an n-type multilayer-film mirror 1002 is provided on an n-type semiconductor substrate 1001 formed of a GaAs layer as a III-V group compound semiconductor. The n-type multilayer-film mirror (DBR) 1002 is a stack body in which 45 pairs of an Al_{0.8}GaAs layer (68.1-nm-thick) and an Al_{0.3}GaAs layer (62-nm-thick) as III-V group compound semiconductors are repetitively stacked.

On the multilayer-film mirror (DBR) 1002, an n-type cladding layer 1003 formed of an Al_{0.8}GaAs layer (102.6-nm-thick) is provided. On the n-type cladding layer 1003, an active layer 1004 having a triple quantum well structure formed of a combination of a GaAs well layer (10-nm-thick) and an Al_{0.3}GaAs barrier layer (10-nm-thick) is provided. Also, on the active layer 1004, a p-type cladding layer 1005 formed of an Al_{0.8}GaAs layer (337.4-nm-thick) is further provided.

A movable mirror 1006 is provided on a lower surface of a portion at a distal end side of a silicon cantilever (2-μm-thick) 1007. The silicon cantilever 1007 is supported above the substrate 1001 with multiple layers interposed therebetween, by a silicon oxide layer (1-μm-thick) 1008, the silicon cantilever (2-μm-thick) 1007, a silicon oxide film (2.5-μm-thick) 1009, and a silicon substrate 1010. The movable mirror 1006 is a dielectric DBR in which 10 pairs of a SiO₂ layer (145.5-nm-thick) and a TiO₂ layer (90-nm-thick) are repetitively stacked. The layer thickness of the silicon oxide layer 1008 corresponds to the thickness of the gap portion, and the cavity length in a state in which the movable mirror is not driven is 3λ. Also, a Ti/Au electrode 1011 and a Ti/Au electrode 1012 are formed for application of a voltage to drive the silicon cantilever by an electrostatic attraction.

In this example, the movable mirror 1006 is provided on the lower surface of the portion at the distal end side of the silicon cantilever 1007; however, the movable mirror 1006 may be provided on an upper surface and part of the portion at the distal end side of the silicon cantilever 1007 may be removed.

Also, the cladding layer 1005 has a current confinement layer 1013 formed by ion implantation with protons in part of the p-type cladding layer 1005. Hence, current supplied from an electrode 1016 passes through an opening portion 1015 of the current confinement layer 1013, and is injected to the active layer 1004. As an electrode for driving the wavelength variable VCSEL of this example, an electrode 1016 uses a metal multilayer film formed of a Ti layer (20 nm) and an Au layer (100 nm). Also, an electrode 1017 uses a metal multilayer film formed of mixed crystal of Au and Ge (100 nm), Ni (20 nm), and Au (100 nm). Reference sign 1019 denotes a power supply for driving VCSEL.

Also, the electrodes 1014 and 1012 each use a metal multilayer film formed of a Ti layer (20 nm) and an Au layer (100 nm).

In this example, a silicon MEMS structure formed by processing a silicon on insulator (SOI) substrate is used as a drive unit having the emission-side movable mirror (upper mirror) 1006. In the drive unit, the compound semiconductor substrate 1001 having formed thereon the lower multilayer-film mirror (DBR) 1002, the lower cladding layer 1003, the active layer 1004, the upper cladding layer 1005, etc., is bonded, and hence a wavelength variable VCSEL 10 is configured.

In this example, it is assumed that a light emission region determined by a proton injection region, that is, the opening portion 1015 of the current confinement structure formed by ion implantation with protons has a circular shape with a diameter of 5 μm.

In this example, a movable portion 1018 is provided. By displacing the movable portion 1018, the movable mirror (upper reflecting mirror) 1006, and the multilayer-film mirror (lower reflecting mirror) 1002 as described above, a mode hop can be restricted, and the wavelength variable width can be enlarged.

Next, a manufacturing method of the wavelength variable VCSEL according to this example is described.

First, the multilayer-film mirror (n-type semiconductor DBR) 1002, the n-type cladding layer 1003, the active layer 1004, and the p-type cladding layer 1005 are successively stacked on the n-type semiconductor substrate 1001 formed of a GaAs layer by using a metal organic chemical vapor deposition (MOCVD) crystal growth technology.

Then, a silicon oxide film is formed on the p-type cladding layer 1005, and is processed by a photolithography technology and an etching technology to serve as a mask when protons are injected for forming the current confinement structure. After the mask of the silicon oxide film (not shown) is formed, protons are injected, and hence the current confinement structure is formed. Alternatively, to form the current confinement structure, an AlGaAs layer (30-nm-thick) with an Al composition of 90% or higher may be arranged in the cladding layer 1005, and the portion may be selectively oxidized in the x-axis direction from the side surface to be converted into aluminum oxide hence to be a region with high resistance.

Then, the electrode 1016 is formed by using a photolithography technology, a vacuum deposition technology, and a lift-off technology.

Then, the cathode electrode 1017 for driving VCSEL is formed on the back surface of the semiconductor substrate 1001 by using a vacuum deposition technology, and thus a compound semiconductor light emitting element is completed.

Alternatively, the conductive types of the respective semiconductor layers in the above-described example may be inverted. In particular, the p-type semiconductor layer may be the n-type semiconductor layer, and the n-type semiconductor layer may be the p-type semiconductor layer. The dopant of the p-type semiconductor layer may use Zn, and the dopant of the n-type semiconductor layer may use C; however, it is not limited thereto.

It is expected that the wavelength variable VCSEL of this example performs wavelength sweeping in the variable wavelength band of ±50 nm around the wavelength of 850 nm. However, the wavelength band is not limited to this wavelength band. By properly selecting the materials of the respective layers configuring the VCSEL, for example, wavelength sweeping may be performed in a wavelength band of ±50 nm around the wavelength of 1060 nm.

### Example 3

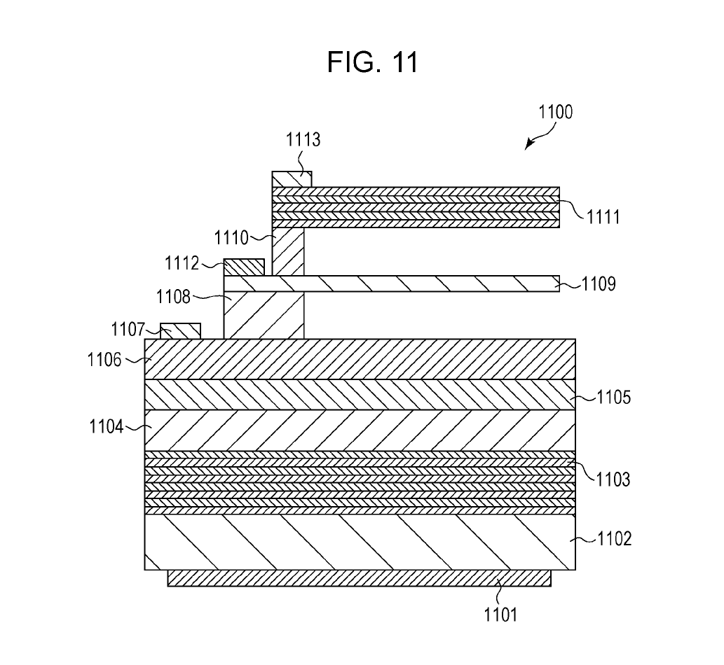

A surface emitting laser according to EXAMPLE 3 is described with reference to FIG. 11. FIG. 11 is a schematic cross-sectional view showing a layer structure of VCSEL according to this example.

VCSEL 1100 according to this example includes a cathode electrode 1101 for driving VCSEL, an n-type substrate 1102 configured of GaAs, an n-type lower DBR 1103 formed by alternately stacking AlAs and GaAs by 40.5 pairs, an n-type lower spacer layer 1104 configured of Al_{0.7}Ga_{0.3}As, an undoped active layer 1105 configured of a multilayer quantum well layer formed of a quantum well layer of InGaAs and a barrier layer of GaAsP, a p-type upper spacer layer 1106 configured of Al_{0.7}Ga_{0.3}As in that order. Also, an electrode 1107 for driving VCSEL and for driving upper DBR is formed on the upper spacer layer 1106. Further, an undoped GaAs layer 1108, an n-type slab portion 1109 configured of Al_{0.7}Ga_{0.3}As, an undoped GaAs layer 1110, an n-type upper DBR 1111 formed by arranging Al_{0.7}Ga_{0.3}As at the upper and lower outermost layers and alternately stacking Al_{0.9}Ga_{0.1}As and Al_{0.4}Ga_{0.6}As by 30 pairs between the upper and lower outermost layers, electrodes 1112 and 1113 for driving upper DBR 1112 are formed on the upper spacer layer 1106.

The structure of this example is fabricated by using a typical semiconductor process technology such as epitaxial growth, photolithography, dry etching, wet etching, vacuum deposition, etc., similarly to the technologies described in EXAMPLES 1 and 2.

A semiconductor multilayer film is formed by on the substrate 1102 epitaxial growth to the upper DBR 1111.

Next, photolithography and dry etching are performed by two times, and a beam structure including the slab portion 1109 and the upper DBR 1111 are patterned. At this time, it is assumed that the depth of the dry etching is a depth that causes the GaAs sacrificial layer 1108 to be exposed.

Next, portions of the GaAs sacrificial layer 1108 and the GaAs sacrificial layer 1110 are removed by wet etching using a mixed solution of a citric acid solution and aqueous hydrogen peroxide, and hence the beam structure is formed. At this time, if portions of the sacrificial layers are covered with photoresist or the like, the region of the portions of the sacrificial layers can be left without being removed.

Next, the electrode 1107, the electrode 1112, and the electrode 1113 are formed by using photolithography, vacuum deposition, and lift-off.

Next, the cathode electrode 1101 for driving VCSEL is formed on the back surface of the semiconductor substrate 1102 by using a vacuum deposition technology, and thus a compound semiconductor light emitting element is completed.

With the surface emitting laser according to the exemplary embodiment and the examples of the invention, by displacing at least two of the movable portion provided in the gap portion of the surface emitting laser, the upper reflecting mirror, and the lower reflecting mirror in the optical-axis direction, and aligning the position with a large light-intensity distribution in a specific longitudinal mode with the position of the active layer, oscillation can be easily continued in a certain longitudinal mode. Consequently, a mode hop in a longitudinal mode can be restricted, and the wavelength variable width can be enlarged.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-135388 filed Jun. 30, 2014, which is hereby incorporated by reference herein in its entirety.

What is claimed is:

1. A surface emitting laser including a lower reflecting mirror, an active layer, and an upper reflecting mirror in that order, and having a gap portion between the active layer and the upper reflecting mirror, the surface emitting laser comprising:
a movable portion provided on an optical path of the gap portion and having a refractive index different from a refractive index of the gap portion,
wherein a wavelength of light to be emitted is changed by changing positions in an optical-axis direction of at least two of the movable portion, the upper reflecting mirror, and the lower reflecting mirror.

2. The surface emitting laser according to claim 1, wherein positions in the optical-axis direction of the upper reflecting mirror or the lower reflecting mirror and the movable portion are changed so that an amplitude of a light intensity between the movable portion and the lower reflecting mirror is larger than an amplitude of a light intensity between the movable portion and the upper reflecting mirror, and thus the movable portion changes the wavelength of the light to be emitted.

3. The surface emitting laser according to claim 1, wherein a center in the optical-axis direction of the movable portion is located between a certain single loop and a neighbor lower node of a standing light wave formed in a cavity configured of the upper reflecting mirror and the lower reflecting mirror.

4. The surface emitting laser according to claim 1, wherein the movable portion has an optical thickness in the optical-axis direction, the optical thickness being in a range larger than 0 and smaller than ½ of a center wavelength of the surface emitting laser or being a thickness obtained by adding an integral multiple of ½ of the center wavelength to the optical thickness in the range.

5. The surface emitting laser according to claim 1, wherein the movable portion has an optical thickness in the optical-axis direction, the optical thickness being in a range larger than ⅛ and smaller than ⅜ of a center wavelength of the surface emitting laser or being a thickness obtained by adding an integral multiple of ½ of the center wavelength of the surface emitting laser to the optical thickness in the range.

6. The surface emitting laser according to claim 1, wherein the movable portion has a thickness in the optical-axis direction of 130 nm or smaller.

7. The surface emitting laser according to claim 1, wherein the movable portion has a thickness in the optical-axis direction in a range from 35 nm to 105 nm.

8. The surface emitting laser according to claim 1, wherein a ratio of a displacement of the movable portion to a displacement of at least one of the upper reflecting mirror and the lower reflecting mirror is 1:2.

9. The surface emitting laser according to claim 1, wherein at least two of the movable portion, the upper reflecting mirror, and the lower reflecting mirror are displaced synchronously.

10. The surface emitting laser according to claim 1, wherein at least two of the movable portion, the upper reflecting mirror, and the lower reflecting mirror are displaced in the same period.

11. A surface emitting laser including a lower reflecting mirror, an active layer, and an upper reflecting mirror in that order, having a gap portion between the active layer and the upper reflecting mirror, and configured to change a wavelength of light to be emitted, the surface emitting laser comprising:
a movable portion provided on an optical path of the gap portion and having a refractive index different from a refractive index of the gap portion,
wherein the movable portion, the upper reflecting mirror, and the lower reflecting mirror are positioned so that an amplitude of a standing light wave formed between the movable portion and the lower reflecting mirror is larger than an amplitude of a standing light wave formed between the movable portion and the upper reflecting mirror.

12. An optical coherence tomography comprising:
a light-source unit configured to change a wavelength of light;
an interference optical system configured to split the light from the light-source unit into irradiation light that is emitted on an object and reference light, and generate interfering light from reflected light of the light emitted on the object and the reference light;
a light detecting unit configured to receive the interfering light; and
an information acquiring unit configured to process a signal from the light detecting unit and acquires information of the object,
wherein the light-source unit is the surface emitting laser according to claim 1.
